(19) United States
(12) Patent Application Publication
(10) Pub. No.: US 2007/0217159 A1
(43) Pub. Date: Sep. 20, 2007

(54) CLIP ASSEMBLY FOR ATTACHING A HEAT SINK TO AN ELECTRONIC DEVICE

(75) Inventors: Jun Long, Shenzhen (CN); Yong Zhong, Shenzhen (CN); Wan-Lin Xia, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/309,432

(22) Filed: Aug. 4, 2006

(30) Foreign Application Priority Data
Mar. 17, 2006 (CN) 200610034541.1

(51) Int. Cl. H05K 7/20

(52) U.S. Cl. 361/704

(57) ABSTRACT

A clip assembly includes a bolt, a sleeve, and a resilient component held between the bolt and the sleeve. The bolt includes a head formed at an end thereof, an engaging portion formed at an opposite end thereof, and an engaging structure located between the head and the engaging portion. The sleeve includes a hollow body having an engaging structure. When the bolt is inserted into the body of the sleeve along a first direction, the engaging structure of the bolt engages with the engaging structure of the sleeve to block the bolt from escaping from the sleeve along a second direction opposite to the first direction. The resilient component is adapted to exert a force on the bolt to cause the bolt to have a tendency to move along the second direction.

### FIELD OF THE INVENTION

The present invention relates to a clip assembly, and more particularly to a clip assembly for attaching a heat sink to an electronic package.

### DESCRIPTION OF RELATED ART

A heat sink is usually placed in thermal contact with an electronic package, such as a central processing unit (CPU), to transfer heat through conduction away from the electronic package thus preventing over-heating of the electronic package. One apparatus for attaching the heat sink on the CPU includes four through holes defined in four corners of the heat sink, four thread holes defined in a motherboard, four screws, and four springs. The screws are extended through the springs and the through holes of the heat sink in order to engage in the thread holes of the motherboard, thereby attaching the heat sink onto the CPU.

However, the screws and the springs are discrete components prior to attachment of the heat sink onto the motherboard. Particularly in mass-production facilities, the assembly process can be time-consuming and inconvenient.

Therefore, an improved apparatus for securing a heat sink, which overcomes the above-mentioned problem is desired.

### SUMMARY OF THE INVENTION

A clip assembly comprises a bolt, a sleeve, and a resilient component exerting a force on both the bolt and the sleeve. The bolt comprises a head formed at an end thereof, an engaging portion formed at an opposite end thereof, and an engaging structure located between the head and the engaging portion. The sleeve comprises a hollow body having an engaging structure. When the bolt is inserted into the body of the sleeve along a first direction, the engaging structure of the bolt engages with the engaging structure of the sleeve to stop the bolt from escaping from the sleeve along a second direction opposite to the first direction. The resilient component exerts a force on the bolt to cause the bolt to have a tendency to move along the second direction.

Other advantages and novel features will become more apparent from the following detailed description of preferred embodiments when taken in conjunction with the accompanying drawings, in which:

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded view of a clip assembly in accordance with a preferred embodiment of the present invention, together with a heat sink, a printed circuit board and an electronic package mounted on the printed circuited board;

FIG. 2 is an enlarged exploded view of the clip assembly in FIG. 1;

FIG. 3 is a schematic cutaway view showing the heat sink placed onto the electronic package in position for its subsequent mounting on the printed circuited board by the clip assembly;

FIG. 4 is a schematic cutaway view showing that the heat sink mounted to the printed circuited board by the clip assembly; and

FIG. 5 is an assembled view of FIG. 1.

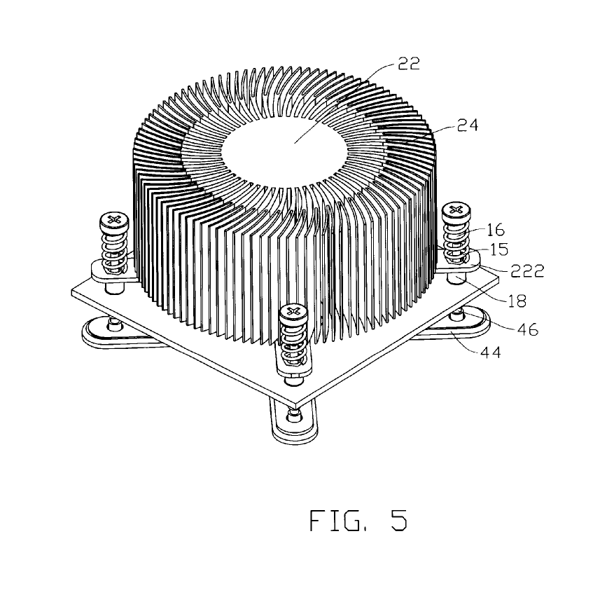

### DETAILED DESCRIPTION OF THE INVENTION

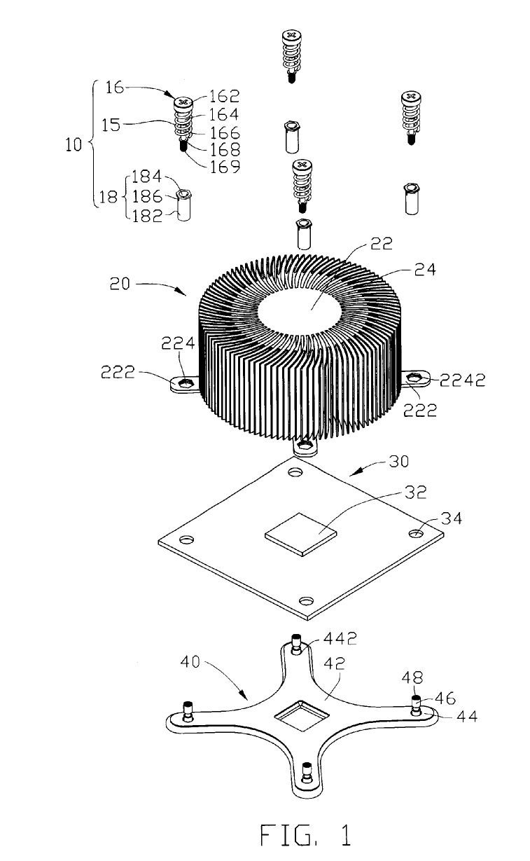

Referring to FIGS. 1 -5, a clip assembly 10 in accordance with a preferred embodiment of the present invention is illustrated. The clip assembly 10 is used to secure a heat sink 20 to an electronic package such as a CPU 32 mounted on a printed circuit board 30, which has four through holes 34 defined around the CPU 32. In this embodiment, a back plate 40 is provided for engaging with the clip assembly 10 so as to secure the heat sink 20 to the printed circuit board 30.

The heat sink 20 comprises a cylindrical core 22 and a plurality of fins 24 radially and outwardly extending from a periphery of the core 22. Four ears 222 symmetrically and outwardly extend from a bottom portion of the core 22. Each ear 222 has a through hole 224 defined in a free end portion thereof corresponding to the through holes 34 of the printed circuit board 30. An annular step 2242 is inwardly disposed in a lower end of the through hole 224 of each ear 222 of the heat sink 20. An upper end of each through hole 224 has a hexagonal cross-section. The lower end of each through hole 224 has an inner diameter smaller than a diameter of the upper end of the through hole 224, and has a cylindrical cross-section.

The back plate 40 is located under the printed circuit board 30 opposite the CPU 32. The back plate 40 comprises a rectangular base 42 abutting against a bottom side of the printed circuit board 30, and four arms 44 symmetrically and outwardly extending from corners of the base 42. Each arm 44 defines an aperture 442 in a free end thereof for an extending socket 46 to extend therethrough. A center of each extending socket 46 defines a thread hole 48 therein for receiving and threadly engaging with the clip assembly 10.

The clip assembly 10 comprises a bolt 16, a sleeve 18, and a resilient component, such as a coil spring 15 held between the sleeve 18 and the bolt 16.

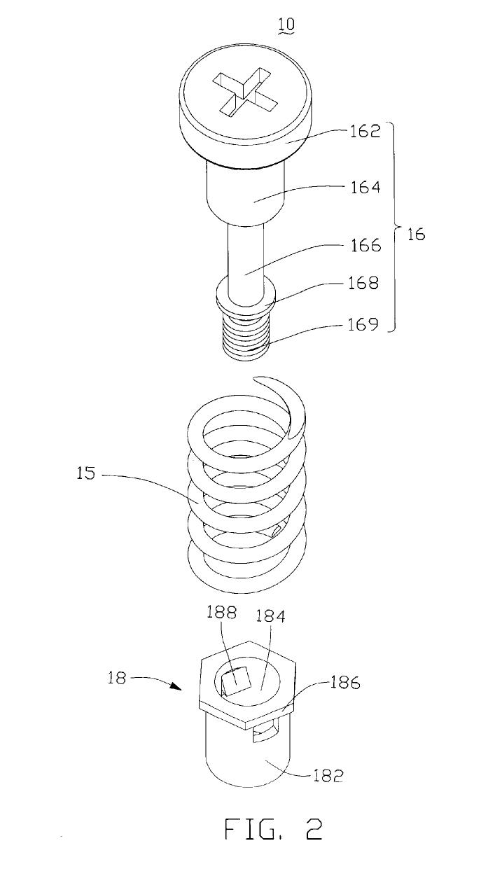

Particularly referring to FIG. 2, the bolt 16 is a multistage body with different diameters, comprises a rounded head 162, a first section 164 extending downwards from the head 162, and a second section 166 depending from a bottom portion of the first section 164. The second section 166 has a diameter smaller than a diameter of the first section 164.

The head 162 is formed at a top end of the bolt 16, and has a cross-shaped groove (not labeled) defined in a top side thereof for engaging with tools, which can screw the bolt 16 downwardly. The head 162 has a diameter larger than a diameter of the adjacent first section 164 so as to form a flange.

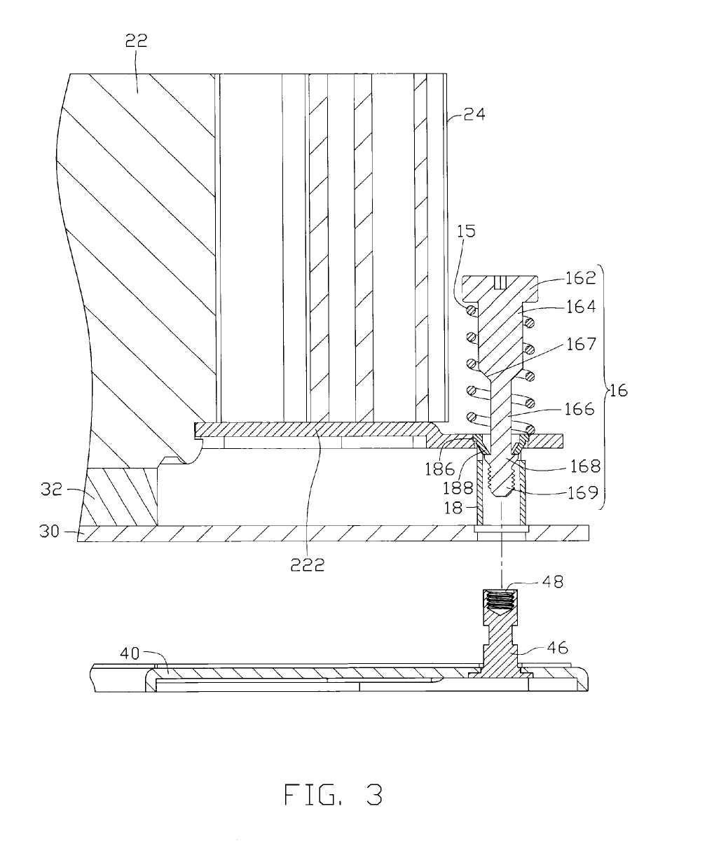

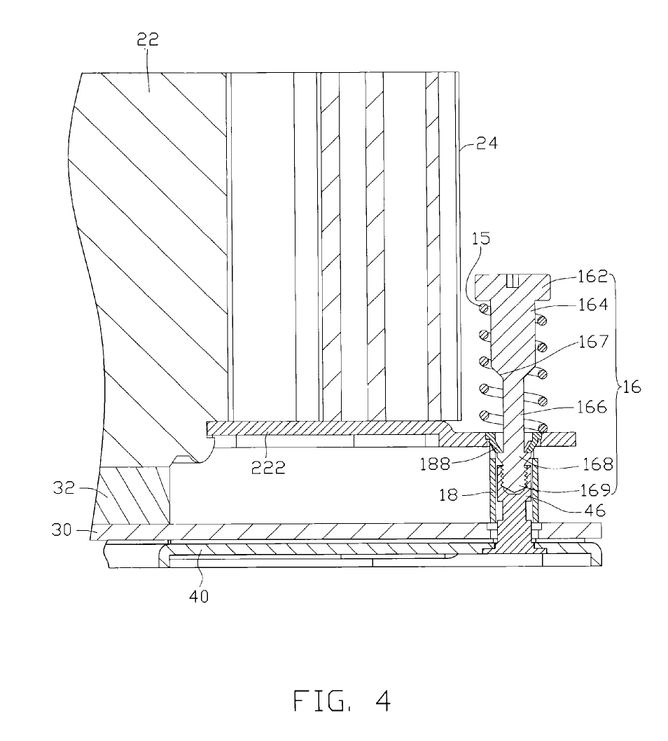

The first section 164 has an outer diameter substantially identical to an inner diameter of the coil spring 15; thus, the coil spring 15 can be coaxially positioned on the first section 164 of the bolt 16. The first section 164 further has a cone portion 167 (see FIG. 3-4) formed at the joint portion of the first section 164 and the second section 166 so as to reduce the stress concentrating thereat.

The second section 166 has an engaging portion 169 formed at a free end thereof. The engaging portions 169 can extend downwards through the through holes 224 of the heat sink 20 and the through holes 34 of the printed circuit board 30 to engage with the extending sockets 46. In this embodiment, the engaging portions 169 each form a thread portion for engaging in the thread holes 48 of the extending sockets 46. A ring shaped projection 168 is formed at the second section 166 above and adjacent to the engaging portion 169. In this embodiment, the projection 168 has a cone shaped outer surface (see FIG. 3-4), which facilitates mounting the bolt 16 into the sleeve 18.

The sleeve 18 comprises an elongated hollow body 182 and a hexagonally shaped flange 186 formed at a top edge of the body 182. A hole 184 is defined extending through the entire sleeve 18 coaxial with an axis of the body 182. The hole 184 of the sleeve 18 has a diameter larger than an outer diameter of the projection 168 of the bolt 16. Moreover, the diameter of the hole 184 of the sleeve 18 is slightly larger than an outer diameter of the extending socket 46 so that the extending socket 46 can move upwardly into the hole 184; thus, the extending socket 46 can be guided to engage with the engaging portion 169 of the bolt 16. A pair of opposite engaging structures, such as two rectangular barbs 188, are stamped inwardly from the body 182 of the sleeve 18, and are slanted downward so as to guide the projection 168 moving downwards.

The flange 186 is snuggly retained on the annular step 2242 of the through holes 224 of the heat sink 20. The outer diameter of the flange 186 of the sleeve 18 is larger than an inner diameter of the coil spring 15 so that the coil spring 15 can be supported on the flange 186 of the sleeve 18.

When assembled, the bolt 16 is first pushed to extend through the coil spring 15, then is inserted downwards into the hole 184 of the sleeve 18. The projection 168 of the bolt 16 contacts the barbs 188 of the sleeves 18, forces the bars 188 to move outwards so as to slide past the barbs 188. Subsequently, the barbs 188 return to their previous forms, and block the projection 168 of the bolt 16 from moving upwardly. At the same time, opposite top and bottom sides of the coil spring 15 are rested respectively on the head 162 of the bolt 16 and the flange 186 of the sleeve 18. The coil spring 15 is compressed, and exerts a force on the head 162 of the bolt 16 to upwardly push the bolt 16 away from the sleeve 18. Therefore, the bolt 16, the coil spring 15 and the sleeve 18 are assembled together to form the clip assembly 10. In this state, the engaging portion 169 of the bolt 16 is shielded by the sleeve 18 so as to not scrape and damage the surrounding electronic components.

During operation, a downward force is exerted on the head 162 of the bolt 16 to overcome the resilient force of the coil spring 15 so as to cause the bolt 16 to move downwardly relative to the sleeve 18. Simultaneously, the engaging portion 169 of the bolt 16 engages with a corresponding component such as the thread hole 48 of the extending socket 46. In this process, the resilient force of the coil spring 15 is gradually increased in proportion to the distance that the bolt 16 moves. When the downward force is disappeared, the bolt 16 returns back to its previous position caused by the resilient force of the coil spring 15, where the projection 168 of the bolt 16 is blocked by the barbs 188 of the sleeve 18.

As described above, the bolt 16, the coil spring 15 and the sleeve 18 of the clip assembly 10 are pre-assembled to form a module. This makes the clip assembly more easy to store, transport and use. Furthermore, the sleeve 18 of the clip assembly 10 serves as a shield preventing the engaging portion 169 of bolt 16 from contacting with nearby electronic components. Additionally, the sleeve 18 also serves as a guide for guiding the engaging portion 169 of the bolt 16 into the thread holes 48 of the extending socket 46 of the back plate 40 in a process of securing the heat sink 20 to the CPU 32 by the clip assembly 10. This process will be described in following text in more detail.

In the process of securing the heat sink 20 to the CPU 32 by the clip assembly 10, the pre-assembled clip assemblies 10 are first extended through the associated through holes 224 of the heat sink 20 with the flanges 186 of the sleeves 18 supported on the inserting steps 2242 of the associated through holes 224 of the heat sink 20. Then, the extending sockets 46 of the back plate 40 are pushed upwardly to extend through the corresponding through holes 34 of the printed circuit board 30, and are guided into the corresponding holes 184 of the sleeves 18. Therefore, the engaging portions 169 of the bolts 16 are aimed at the corresponding thread holes 48 of the extending sockets 46. Subsequently, the thread portions of the bolts 16 are screwed downwards to engage in the thread holes 48 of the extending sockets 46. Therefore, the heat sink 20 is mounted on the printed circuit board 30, and the coil springs 15 exert a certain resilient force onto the heat sink 20 via the flanges 186 of the sleeves 18 to evenly contact the heat sink 20 with the CPU 32.

As shown in FIGS. 3-4, the bolt 16 is at a same position during the whole assembly process. However, in another embodiment, if adjusting the length of the thread portion of the bolt 16, the length of the extending socket 46 or other parameters, the bolt 16 may move downwards relative to the sleeve 18 to cause the coil springs 15 to be further compressed between the heads 162 of the bolt 16 and the flange 186 of the sleeves 18.

When disassembled, the heat sink 20, the clip assembly 10 and the printed circuit board 30 can be separated from each other so long as the thread portions of the bolts 16 are unscrewed from the thread holes 48 of the extending sockets 266. Then, the clip assembly 10 can easily be used in other heat sinks, or other types of heat sink in a quite similar manner, so long as the other heat sink has a hole defined therein for the clip assembly 10 to extend through. Therefore, the clip assembly 10 has high versatility of use.

In this embodiment, the sleeve 18 can guide the engaging portion 169 of the bolt 16 into the thread hole 48 of the extending socket 46. This facilitates engagement of the bolt 16 in the extending socket 46. The engaging portion 169 of the bolt 16 is hidden in the sleeve 18 before engaging with the extending socket 46. This can prevent the engaging portion 169 of the bolt 16 from scraping the nearby electronic components.

Furthermore, the clip assembly 10 is pre-assembled to form a module. Installation or removal of the clip assembly 10 is thus both quick and simple. Additionally, the coil springs 15 serve to lessen vibrations; therefore, the heat sink 20 can be securely fastened in the desired position on the printed circuit board 30 and is not overly subjected to the vibrations.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A clip assembly, comprising:
a bolt comprising a head formed at an end thereof, an engaging portion formed at an opposite end thereof, and an engaging structure located between the head and the engaging portion;
a sleeve comprising a hollow body, the body comprising an engaging structure, wherein when the bolt is inserted into the body of the sleeve along a first direction, the engaging structure of the bolt engages with the engaging structure of the sleeve to block the bolt from escaping from the sleeve along a second direction opposite to the first direction; and
a resilient component held between the bolt and the sleeve, the resilient component exerting a force on the bolt to cause the bolt to have a tendency to move along the second direction.

2. The clip assembly as claimed in claim 1, wherein the engaging structure of the sleeve comprises a barb stamped inwardly from the body of the sleeve.

3. The clip assembly as claimed in claim 2, wherein the engaging structure of the bolt comprises a projection projecting outwardly from the bolt.

4. The clip assembly as claimed in claim 3, wherein the engaging portion of the bolt is in form of a thread portion.

5. The clip assembly as claimed in claim 1, wherein the resilient component comprises a coil spring.

6. The clip assembly as claimed in claim 5, wherein the sleeve comprises a flange with a diameter larger than an inner diameter of the resilient component, the resilient component engaging with the flange.

7. The clip assembly as claimed in claim 6, wherein the bolt comprises a first section extending from the head, and a second section extending section extending from the first section, and a diameter of the first section is smaller than that of the head, larger than that of second section.

8. The clip assembly as claimed in claim 7, wherein the diameter of the first section is identical to an inner diameter of the coil spring.

9. An electronic device assembly, comprising:
a printed circuit board having an electronic package mounted thereon, the printed circuit defining a plurality of though holes around the electronic package;
a heat sink attached to the printed circuit board, the heat sink comprising a plurality of through holes defined therein corresponding to the through holes of the printed circuit board; and
a plurality of pre-assembled clip assemblies respectively extending through the through holes of the heat sink, each clip assembly comprising:
a sleeve comprising a hollow body positioned into the through hole of the heat sink, and an engaging structure;
a bolt comprising a head formed at an end thereof, an engaging portion formed at an opposite end thereof, and an engaging structure located between the head and the engaging portion; wherein the bolt is inserted into the body of the sleeve along a first direction and the engaging structure of the bolt engages with the engaging structure of the sleeve to prevent the bolt from escaping from the sleeve along a second direction opposite to the first direction;
a resilient component held between the bolt and the sleeve, the resilient component adapt to preload a force on the bolt to cause the bolt to have a tendency to move along the second direction; and
a plurality of extending sockets respectively extending through the through holes of the printed circuit board and guided by the sleeves to engage with the engaging portions of the bolts to thereby secure the heat sink onto the electronic package.

10. The electronic device assembly as claimed in claim 9, further comprising a back plate attached to one side of printed circuit board opposite to the electronic package, and the extending sockets are extended through the back plate first prior to being extended through the printed circuit board.

11. The electronic device assembly as claimed in claim 9, wherein an inner diameter of the body of the sleeve is larger than an outer diameter of the extending socket, so that the extending socket can be guided into the body of the sleeve.

12. The electronic device assembly as claimed in claim 9, wherein the heat sink comprises a core and a plurality of fins mounted on the core, a plurality of ears extending from an end portion of the core, and the through holes of the heat sink are defined in each of the ears.

13. The electronic device assembly as claimed in claim 12, wherein the fins are radially and outwardly extended from a circumferential periphery of the core.

14. The electronic device assembly as claimed in claim 9, wherein the engaging structure of the sleeve comprises a barb stamped inward from the body of the sleeve, and the engaging structure of the bolt comprises a projection projecting outwardly from the bolt.

15. The electronic device assembly as claimed in claim 9, wherein the engaging portion of the bolt is in form of thread portion, and each extending socket has a thread hole defined therein to engage with the thread portion of the bolt.

16. The electronic device assembly as claimed in claim 9, wherein the sleeve comprises a flange with a diameter larger than an inner diameter of the resilient component, thereby the resilient component indirectly exerts a force on the heat sink via the flange of the sleeve.

17. An electronic assembly comprising:
a printed circuit board having a heat-generating electronic package on a top surface thereof;
a heat sink mounted on the electronic package and in thermal connection therewith;
a back plate attached to a bottom surface of the printed circuit board, the back plate having a plurality of extending sockets extending upwardly through the printed circuit board;
a plurality of clip assemblies each comprising:
a sleeve forming a barb extending into a hole of the sleeve;
a bolt having a head at a top end thereof, an engaging portion at a bottom end thereof, and
a projection between the head and the engaging portion; and
a spring compressed between the head of the bolt and a top of the sleeve, wherein the projection of the bolt is inserted into the hole of the sleeve and engages with the barb to prevent the bolt from moving upwardly;
wherein the sleeve is inserted into the heat sink and the engaging portion securely engages with a corresponding extending socket in the sleeve.

18. The electronic assembly of claim 17, wherein the engaging portion threadedly engages with the corresponding extending socket.

19. The electronic assembly of claim 18, wherein the heat sink has a core from which a plurality of fins extends radially outwardly, and a plurality of ears at a bottom of the heat sink, each ear having a hole defined therein with an upper polygonal void and a step below the upper polygonal void, the sleeve having an upper polygonal flange fitted in the polygonal void and sitting on the step.

20. The electronic assembly of claim 19, where the projection of the bolt is located adjacent to the engaging portion.
